(19) United States
(12) Patent Application Publication
(10) Pub. No.: US 2026/0085794 A1
(43) Pub. Date: Mar. 26, 2026

(54) METHODS AND APPARATUS FOR FLOW BALANCING

(71) Applicant: ASM IP Holding B.V., Almere (NL)

(72) Inventors: Hannelore Azora Hemminger, Tempe, AZ (US); Hang Zhang, Tempe, AZ (US); Qi Qi, Phoenix, AZ (US); Chuwei Chen, Tempe, AZ (US); Todd Robert Dunn, Cave Creek, AZ (US)

(21) Appl. No.: 19/336,700

(22) Filed: Sep. 23, 2025

Related U.S. Application Data
(60) Provisional application No. 63/699,221, filed on Sep. 26, 2024.

(51) Int. Cl. F17C 13/04; F17C 7/00

(52) U.S. Cl. CPC F17C 13/04; F17C 7/00; F17C 2225/0123; F17C 2227/048; F17C 2250/043; F17C 2250/06; F17C 2270/05

(57) ABSTRACT

Various embodiments of the present technology may provide a vessel coupled to a first reaction chamber and a second reaction chamber via a first gas line and second gas line, respectively. Each gas line may comprise a variable feature, wherein each flexible feature is configured to change the flow dynamics of a gas flowing through the gas lines.

### CROSS-REFERENCE TO RELATED APPLICATIONS

This application is a nonprovisional of, and claims priority to and the benefit of, U.S. Provisional Patent Application No. 63/699,221, filed Sep. 26, 2024 and entitled “METHODS AND APPARATUS FOR FLOW BALANCING,” which is hereby incorporated by reference herein.

### FIELD OF INVENTION

The present disclosure generally relates to a method and apparatus for flow balancing. More particularly, the present disclosure relates to balancing the gas flow from a vessel to a first reaction chamber and a second reaction chamber.

### BACKGROUND OF THE TECHNOLOGY

Some semiconductor manufacturing systems have multiple reaction chambers coupled to a single chemical source via multiple gas lines. The flow dynamics in each gas line may vary which leads to process mismatching among the various reaction chambers.

### SUMMARY OF THE INVENTION

Various embodiments of the present technology may provide a vessel coupled to a first reaction chamber and a second reaction chamber via a first gas line and second gas line, respectively. Each gas line may comprise a variable feature, wherein each flexible feature is configured to change the flow dynamics of a gas flowing through the gas lines.

According to one aspect, an apparatus comprises: a vessel; a first reaction chamber fluidly coupled to the vessel via a first gas line, wherein the first gas line comprises a first feature formed from a material that allows the first feature to have varying sizes; and a second reaction chamber fluidly coupled to the vessel via a second gas line, wherein the second gas line comprises a second feature formed from a material that allows the first feature to have varying sizes.

In one embodiment, each of the first and second features comprise a restrictor, having an aperture with a diameter, formed from a metallic material, wherein the diameter of the aperture varies according to temperature.

In one embodiment, the apparatus further comprises a first heating element disposed adjacent the first feature and a second heating element disposed adjacent the second feature.

In one embodiment, the apparatus further comprises a controller in communication with the first and second heating elements, wherein the controller is configured to operate the first heating element independently from the second heating element.

In one embodiment, wherein each of the first and second features comprise a pipe portion having a least one of a compressible and expandable length and a compressible and expandable diameter.

In another aspect, an apparatus comprises: a vessel; a first reaction chamber fluidly coupled to the vessel via a first gas line, wherein the first gas line comprises a first flexible membrane coupled to a first end of a tube; and a second reaction chamber fluidly coupled to the vessel via a second gas line, wherein the second gas line comprises a second flexible membrane coupled to a second end of the tube.

In one embodiment, the tube comprises an incompressible fluid within an interior volume of the tube.

In one embodiment, the first flexible membrane is arranged within a sidewall of the first gas line, and the second flexible membrane is arranged within a sidewall of the second gas line.

In one embodiment, the apparatus further comprises a first valve in line with the first gas line; and a second valve in line with the second gas line.

In one embodiment, the first and second valves are arranged upstream from the first and second flexible membranes.

In yet another aspect, an apparatus comprises: a vessel; a first reaction chamber fluidly coupled to the vessel via a first gas line; a second reaction chamber fluidly coupled to the vessel via a second gas line; a first variable feature disposed within the first gas line; and a second variable feature disposed within the second gas line; wherein each of the first and second flexible features are configured to change the flow dynamics of a gas flowing through the respective gas line.

In one embodiment, the apparatus further comprises a first pressure sensor disposed between the first variable feature and the first reaction chamber; and a second pressure sensor disposed between the second variable feature and the second reaction chamber.

In one embodiment, the first variable feature comprises a first flexible membrane arranged within a sidewall of the first gas line, and the second variable feature comprises a second flexible membrane arranged within a sidewall of the second gas line.

In one embodiment, the apparatus further comprises a tube comprising a first end coupled to the first flexible membrane and a second end coupled to the second flexible membrane.

In one embodiment, the tube comprises an incompressible fluid within an interior volume of the tube.

In one embodiment, the apparatus further comprises a first valve in line with the first gas line; and a second valve in line with the second gas line, wherein the first and second valves are arranged upstream from the first and second flexible membranes.

In one embodiment, each of the first and second variable features comprise a pipe portion having a least one of a compressible and expandable length and a compressible and expandable diameter.

In one embodiment, each of the first and second variable features comprise a restrictor, having an aperture with a diameter, formed from a metallic material, wherein the diameter of the aperture varies according to temperature.

In one embodiment, the apparatus further comprises a first heating element disposed adjacent the first variable feature and a second heating element disposed adjacent the second variable feature.

In one embodiment, the apparatus further comprises a controller in communication with the first and second heating elements, wherein the controller is configured to operate the first heating element independently from the second heating element.

### BRIEF DESCRIPTION OF THE DRAWING FIGURES

A more complete understanding of the present technology may be derived by referring to the detailed description when considered in connection with the following illustrative figures. In the following figures, like reference numbers refer to similar elements and steps throughout the figures.

FIG. 1 representatively illustrates a system in accordance with embodiments of the present technology;

FIG. 2 is a partial view of the system in accordance with embodiments of the present technology;

FIG. 3 is a partial view of the system in accordance with embodiments of the present technology;

FIG. 4 is a partial view of the system in accordance with embodiments of the present technology; and

FIG. 5 is a partial view of the system in accordance with embodiments of the present technology.

### DETAILED DESCRIPTION OF EXEMPLARY EMBODIMENTS

The present technology may be described in terms of functional block components and various processing steps. Such functional blocks may be realized by any number of components configured to perform the specified functions and achieve the various results. For example, the present technology may employ various gas lines, valves, controllers, reaction chambers, vessels, and susceptors.

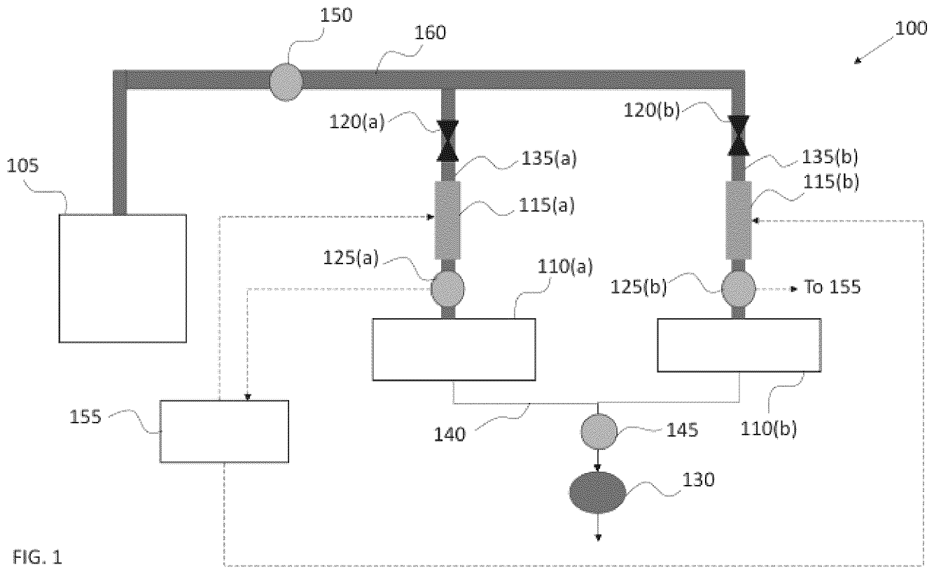

Referring to FIG. 1, an exemplary system 100 may comprise a first reaction chamber 110(a) and a second reaction chamber 110(b), wherein each reactor is configured to perform processing on an object to be processed, such as a substrate (e.g., a wafer). For example, each reaction chamber 110(a), 110(b) may be configured to perform heating, deposition, etching, polishing, ion implantation, and/or other processing on the object to be processed. In some embodiments, the reaction chambers 110(a), 110(b) may be configured to perform a movement function, a vacuum sealing function, and an exhaust function. In some embodiments, the reaction chambers 110(a), 110(b) may perform various semiconductor manufacturing processes, such as an atomic layer deposition (ALD) process or a chemical vapor deposition (CVD) process.

In various embodiments, the system 100 may further comprise a substrate mounting unit (not shown) disposed within the reaction chambers. The substrate mounting unit may comprise a susceptor for supporting the substrate and a heater for heating the substrate supported by the susceptor. The heater may be embedded within the susceptor. The substrate mounting unit may further comprise a pedestal to support the susceptor. For loading/unloading of the substrate, the substrate mounting unit may be configured to be vertically movable (up and down) by being connected to a driving unit (not shown).

In various embodiments, the system 100 may further comprise a gas distribution system for delivering a vapor into the reaction chambers 110(a), 110(b). In an exemplary embodiment, the gas distribution system may comprise a plurality of gas lines, such as a first gas line 135(a) and a second gas line 135(b). The first and second gas lines 135(a), 135(b) may be coupled to a main gas line 160. In addition, the first gas line 135(a) may be directly coupled to the first reaction chamber 110(a) and the second gas line 135(b) may be coupled to the second reaction chamber 110(b).

In various embodiments, the system 100 may further comprise a vessel 105 configured to contain a chemical (i.e., a precursor). The vessel 105 may be configured to hold a solid or a liquid chemical, and may further be configured to transform the solid or liquid into a vapor. The vessel 105 may be coupled to the gas distribution system to flow the vapor from the vessel 105 to the reaction chambers 110(a), 110(b). In an exemplary embodiment, the gas distribution system is configured to flow the vapor equally into the first and second reaction chambers 110(a), 110(b). For example, the main gas line 160 may be directly coupled to the vessel 105 to provide the vapor to the reaction chambers 110(a), 110(b) via the first and second gas lines 135(a), 135(b), respectively.

In various embodiments, the system 100 may further comprise a plurality of variable features, such as a first variable feature 115(a) and a second variable feature 115(b). The variable features may be configured to change the flow dynamics of the vapor/gas flowing through the gas distribution system. For example, in various embodiments, the first and second variable features 115(a), 115(b) may be disposed within the first and second gas lines 135(a), 135(b), respectively.

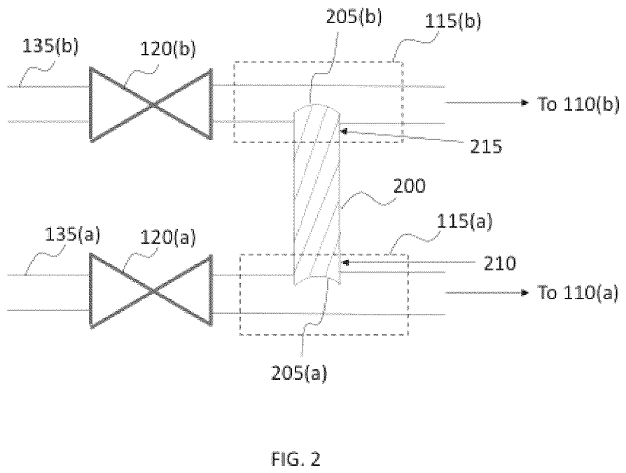

In one embodiment, and referring to FIG. 2, the first variable feature 115(a) may comprise a first flexible membrane 205(a) arranged within a sidewall of the first gas line 135(a), and the second variable feature 115(b) may comprise a second flexible membrane 205(b) arranged within a sidewall of the second gas line 135(b). In the present embodiment, the system 100 may further comprise a tube 200 comprising a first end 210 coupled to the first flexible membrane 205(a) and a second end 215 coupled to the second flexible membrane 205(b). The tube 200 may comprise an incompressible fluid (i.e., a fluid whose volume or density does not change with pressure), water, oil, a hydraulic fluid, or the like, within its interior volume.

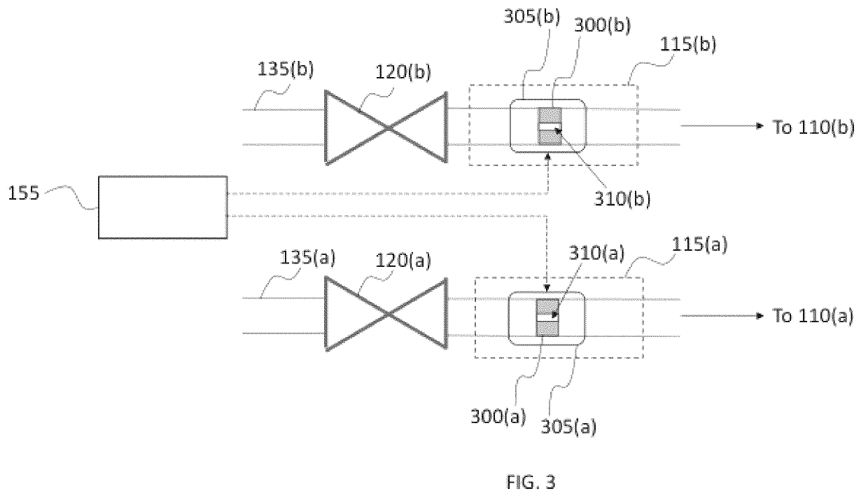

In another embodiment, and referring to FIG. 3, the first variable feature 115(a) may comprise a first restrictor 300(a) and the second variable feature 115(b) may comprise a second restrictor 300(b). The first and second restrictors 300(a), 300(b) may be formed from a metal material capable of thermal expansion, such as stainless steel or a metal alloy (e.g., Hastelloy). Each restrictor 300(a), 300(b) may comprise a respective aperture, such as a first aperture 310(a) and a second aperture 310(b), each aperture having a diameter. The present embodiment may further comprise a heating element, such as a first heating element 305(a) disposed on and/or adjacent to the first restrictor 300(a) and a second heating element 305(b) disposed on and/or adjacent to the second restrictor 300(b). The first and second heating elements 305(a), 305(b) may comprise any suitable heating device, such as a resistive heating element, heating coil or the like. When heated, the first and second restrictors 300(a), 300(b) may expand, thus expanding the diameter of the respective aperture 310(a), 310(b).

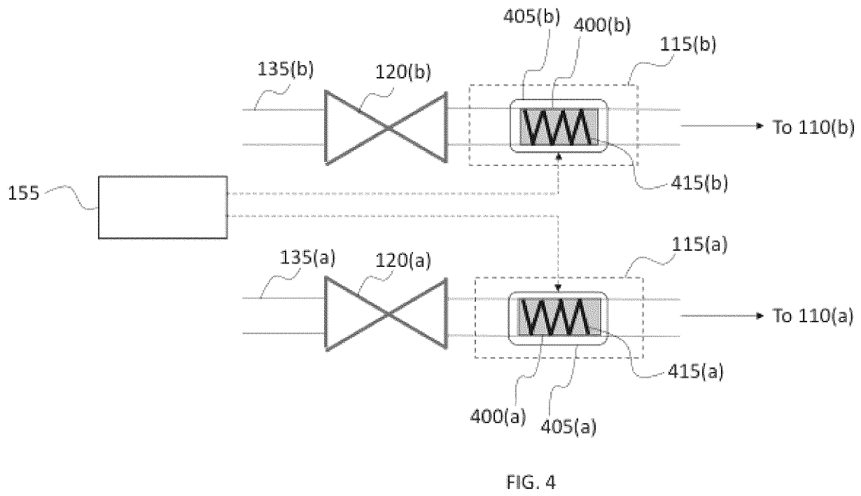

In another embodiment, and referring to FIG. 4, each variable feature 115(a), 115(b) may comprise a pipe portion having a compressible and/or expandable length. The pipe portion may also have a compressible and/or expandable diameter. For example, the first variable feature 115(a) may comprise a first pipe section 400(a) formed from an elastic material or other material that allows for expansion and contraction. For example, the first pipe sections 400(a) may comprise a plastic (e.g., polyethylene), a metal mesh, or the like. The first pipe section 400(a) may further comprise a first coil spring 415(a) disposed on an outer surface of the first pipe section 400(a), embedded within the first pipe section 400(a), or disposed on an inner surface of the first pipe section 400(a). Similarly, the second variable feature 115(a) may comprise a second pipe section 400(b) formed from an elastic material or other material that allows for expansion and contraction. For example, the second pipe sections 400(b) may comprise a plastic (e.g., polyethylene), a metal mesh, or the like. The second pipe section 400(b) may further comprise a second coil spring 415(b) disposed on an outer surface of the second pipe section 400(b), embedded within the second pipe section 400(b), or disposed on an inner surface of the second pipe section 400(b).

In the present embodiment, the system 100 may further comprise a clamping device to provide a compressive force on the coil springs. For example, the system 100 may comprise a first clamping device 405(a) arranged on or adjacent to the ends of the first pipe section 400(a) to reduce the length of the first pipe section 400(a). The system 100 may further comprise a second clamping device 405(b) arranged on or adjacent to the ends of the second pipe section 400(b) to reduce the length of the second pipe section 400(b).

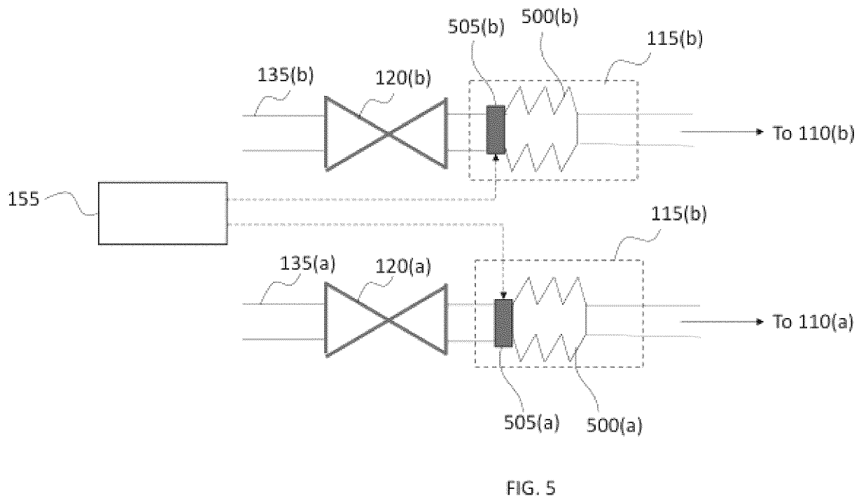

Similarly, and referring to FIG. 5, the first variable feature 115(a) may comprise a first bladder 500(a) that can be contracted and expanded with an attached first actuator 505(a). The second variable feature 115(b) may comprise a second bladder 500(b) that can be contracted and expanded with an attached second actuator 505(b). The first and second bladders may be formed from a plastic material. The actuators may comprise any suitable type of actuator that is capable of compressing the bladder.

In various embodiments, and referring back to FIG. 1, the system 100 may further comprise a plurality of valves, such as a first valve 120(a) and a second valve 120(b). The first valve 120(a) may be inline with the first gas line 135(a) and arranged upstream from the first variable feature 115(a). The second valve 120(b) may be inline with the second gas line 135(b) and arranged upstream from the second variable feature 115(b).

In various embodiments, the system 100 may further comprise a plurality of sensors to measure the pressure of the gas and/or a flow parameter (e.g., conductance) of the gas through the gas lines. For example, the plurality of sensors may comprise a pressure sensor, a flow meter, or the like. In an exemplary embodiment, the system 100 may comprise a first sensor 125(a) arranged between the first variable feature 115(a) and the first reaction chamber 110(a) to measure the pressure and/or conductance of the gas in first gas line 135(a). The system 100 may further comprise a second sensor 125(b) arranged between the second variable feature 115(b) and the second reaction chamber 110(b) to measure the pressure and/or conductance of the gas in the second gas line 135(b). In addition, the system 100 may comprise a third sensor 150 arranged between the vessel 105 and the first and second variable features 115(a), 115(b) to measure the pressure and/or conductance of the gas/vapor in main gas line 160 prior to entering the first and second gas lines 135(a), 135(b).

In various embodiments, the system 100 may further comprise a controller 155 configured to receive and transmit signals. For example, the controller 155 may receive an output signal from the first sensor 125(a), the second sensor 125(b), and/or the third sensor 150, wherein the output signal indicates the measured pressure or conductance of the respective sensor. In various embodiments, the controller 155 may transmit control signals to the first and second variable features 115(a), 115(b). For example, the controller 155 may transmit a control signal to the first and second heating elements 305(a), 305(b) to operate the heating elements independently from each other. In another example, the controller 155 may transmit a control signal to each of the first and second clamping devices 405(a), 405(b) to contract the respective coil springs 415(a), 415(b) and thus contract the length of the first and second pipe sections 400(a), 400(b).

In operation, and referring to FIGS. 1-4, the first and second variable features 115(a), 115(b) can change the flow dynamics of the gas flowing through the first and second gas lines 135(a), 135(b) in order to maintain the same flow/pressure downstream from the first and second variable features 115(a), 115(b), and in particular, the same flow/pressure into the reaction chambers 110(a), 110(b). For example, in the embodiment of FIG. 2, as the flow and/or pressure in the first and second gas lines 135(a), 135(b) that are downstream from the first and second variable features 115(a), 115(b) changes, the pressure on the flexible membranes will change, thus pushing them in or out and causing a change to the flow resistance. The change in flow resistance will eventually reach an equilibrium where both first and second gas lines 135(a), 135(b) have the same static pressure and therefore the same flow rate.

In the embodiment of FIG. 3, the controller 155 may transmit signals to the first and second heating elements 305(a), 305(b) to increase the temperature of the first and second restrictors 300(a), 300(b). When the restrictors are heated, the respective aperture 310 diameter increases, thus resulting in an increased flow through the restrictor. The controller 155 may operate the heating elements independently from each other such that the aperture of one restrictor is larger than the aperture of the other restrictor. The first and second sensors 125(a), 125(b), may provide continuous or periodic pressure data feedback to the controller 155 and the controller 155 may dynamically respond to the pressure data to ensure that the pressure/flow rate downstream from the first and second restrictors 300(a), 300(b) and into the reaction chambers 110(a), 110(b) is substantially equal. For example, if the pressure is higher in one gas line, the controller 155 may operate the heating element to increase the temperature of one restrictor. Alternatively, the controller 155 may increase the temperature of one heating element and decrease the temperature in the other heating element in order to equalize the pressure in both gas lines.

In the embodiment of FIG. 4, the controller 155 may transmit signals to the first and second clamping devices 405(a), 405(b) to exert and force on the respective coil springs 415(a), 415(b), and thus shorten the length of the first and second pipe sections 400(a), 400(b). When the first and second pipe sections 400(a), 400(b) are shortened (or lengthened), pressure and flow dynamics change, such that each first and second pipe section 400(a), 400(b) may have different flow or pressure measurements. The controller 155 may operate the first and second clamping devices 405(a), 405(b) independently from each other such that one pipe section may be shorter than the other pipe section. The first and second sensors 125(a), 125(b), may provide continuous or periodic pressure data feedback to the controller 155, and the controller 155 may dynamically respond to the pressure data to ensure that the pressure/flow rate downstream from the first and second pipe sections 400(a), 400(b) and into the reaction chambers 110(a), 110(b) is substantially equal. For example, if the pressure is higher in one gas line, the controller 155 may operate the clamping device to decrease the pressure in that particular gas line by lengthening that pipe section to equalize the pressure/flow in both gas lines. Alternatively, the controller 155 may increase the pressure/flow to one gas line and decrease the pressure/flow in the other gas line in order to equalize the pressure in both.

In the foregoing description, the technology has been described with reference to specific exemplary embodiments. The particular implementations shown and described are illustrative of the technology and its best mode and are not intended to otherwise limit the scope of the present technology in any way. Indeed, for the sake of brevity, conventional manufacturing, connection, preparation, and other functional aspects of the method and system may not be described in detail. Furthermore, the connecting lines shown in the various figures are intended to represent exemplary functional relationships and/or steps between the various elements. Many alternative or additional functional relationships or physical connections may be present in a practical system.

The technology has been described with reference to specific exemplary embodiments. Various modifications and changes, however, may be made without departing from the scope of the present technology. The description and figures are to be regarded in an illustrative manner, rather than a restrictive one and all such modifications are intended to be included within the scope of the present technology. Accordingly, the scope of the technology should be determined by the generic embodiments described and their legal equivalents rather than by merely the specific examples described above. For example, the steps recited in any method or process embodiment may be executed in any order, unless otherwise expressly specified, and are not limited to the explicit order presented in the specific examples. Additionally, the components and/or elements recited in any apparatus embodiment may be assembled or otherwise operationally configured in a variety of permutations to produce substantially the same result as the present technology and are accordingly not limited to the specific configuration recited in the specific examples.

Benefits, other advantages and solutions to problems have been described above with regard to particular embodiments. Any benefit, advantage, solution to problems or any element that may cause any particular benefit, advantage or solution to occur or to become more pronounced, however, is not to be construed as a critical, required or essential feature or component.

The terms “comprises”, “comprising”, or any variation thereof, are intended to reference a non-exclusive inclusion, such that a process, method, article, composition or apparatus that comprises a list of elements does not include only those elements recited, but may also include other elements not expressly listed or inherent to such process, method, article, composition or apparatus. Other combinations and/or modifications of the above-described structures, arrangements, applications, proportions, elements, materials or components used in the practice of the present technology, in addition to those not specifically recited, may be varied or otherwise particularly adapted to specific environments, manufacturing specifications, design parameters or other operating requirements without departing from the general principles of the same.

The present technology has been described above with reference to an exemplary embodiment. However, changes and modifications may be made to the exemplary embodiment without departing from the scope of the present technology. These and other changes or modifications are intended to be included within the scope of the present technology, as expressed in the following claims.

What is claimed is:

1. An apparatus, comprising:
a vessel;
a first reaction chamber fluidly coupled to the vessel via a first gas line, wherein the first gas line comprises a first feature formed from a material that allows the first feature to have varying sizes; and
a second reaction chamber fluidly coupled to the vessel via a second gas line, wherein the second gas line comprises a second feature formed from a material that allows the first feature to have varying sizes.

2. The apparatus according to claim 1, wherein each of the first and second features comprise a restrictor, having an aperture with a diameter, formed from a metallic material, wherein the diameter of the aperture varies according to temperature.

3. The apparatus according to claim 1, further comprising a first heating element disposed adjacent the first feature and a second heating element disposed adjacent the second feature.

4. The apparatus according to claim 3, further comprising a controller in communication with the first and second heating elements, wherein the controller is configured to operate the first heating element independently from the second heating element.

5. The apparatus according to claim 1, wherein each of the first and second features comprise a pipe portion having a least one of a compressible and expandable length and a compressible and expandable diameter.

6. An apparatus, comprising:
a vessel;
a first reaction chamber fluidly coupled to the vessel via a first gas line, wherein the first gas line comprises a first flexible membrane coupled to a first end of a tube; and
a second reaction chamber fluidly coupled to the vessel via a second gas line, wherein the second gas line comprises a second flexible membrane coupled to a second end of the tube.

7. The apparatus according to claim 6, wherein the tube comprises an incompressible fluid within an interior volume of the tube.

8. The apparatus according to claim 6, wherein the first flexible membrane is arranged within a sidewall of the first gas line, and the second flexible membrane is arranged within a sidewall of the second gas line.

9. The apparatus according to claim 6, further comprising:
a first valve in line with the first gas line; and
a second valve in line with the second gas line.

10. The apparatus according to claim 9, wherein the first and second valves are arranged upstream from the first and second flexible membranes.

11. An apparatus, comprising:
a vessel;
a first reaction chamber fluidly coupled to the vessel via a first gas line;
a second reaction chamber fluidly coupled to the vessel via a second gas line;
a first variable feature disposed within the first gas line; and
a second variable feature disposed within the second gas line;
wherein each of the first and second flexible features are configured to change the flow dynamics of a gas flowing through the respective gas line.

12. The apparatus according to claim 11, further comprising:
a first pressure sensor disposed between the first variable feature and the first reaction chamber; and
a second pressure sensor disposed between the second variable feature and the second reaction chamber.

13. The apparatus according to claim 11, wherein the first variable feature comprises a first flexible membrane arranged within a sidewall of the first gas line, and the second variable feature comprises a second flexible membrane arranged within a sidewall of the second gas line.

14. The apparatus according to claim 13, further comprising a tube comprising a first end coupled to the first flexible membrane and a second end coupled to the second flexible membrane.

15. The apparatus according to claim 14, wherein the tube comprises an incompressible fluid within an interior volume of the tube.

16. The apparatus according to claim 14, further comprising:
a first valve in line with the first gas line; and
a second valve in line with the second gas line, wherein the first and second valves are arranged upstream from the first and second flexible membranes.

17. The apparatus according to claim 11, wherein each of the first and second variable features comprise a pipe portion having a least one of a compressible and expandable length and a compressible and expandable diameter.

18. The apparatus according to claim 11, wherein each of the first and second variable features comprise a restrictor, having an aperture with a diameter, formed from a metallic material, wherein the diameter of the aperture varies according to temperature.

19. The apparatus according to claim 18, further comprising a first heating element disposed adjacent the first variable feature and a second heating element disposed adjacent the second variable feature.

20. The apparatus according to claim 19, further comprising a controller in communication with the first and second heating elements, wherein the controller is configured to operate the first heating element independently from the second heating element.
